(19) United States
(12) Patent Application Publication
(10) Pub. No.: US 2025/0142731 A1
(43) Pub. Date: May 1, 2025

(54) WIRING SUBSTRATE PRODUCTION METHOD, WIRING SUBSTRATE, RETICLE, AND EXPOSURE PATTERN-RENDERING DATA STRUCTURE

(71) Applicant: Resonac Corporation, Minato-ku, Tokyo (JP)

(72) Inventors: Kei TOGASAKI, Minato-ku, Tokyo (JP); Kenichi IWASHITA, Minato-ku, Tokyo (JP); Kensuke YOSHIHARA, Minato-ku, Tokyo (JP); Masaya TOBA, Minato-ku, Tokyo (JP)

(21) Appl. No.: 18/837,891

(22) PCT Filed: Feb. 15, 2023
(86) PCT No.: PCT/JP2023/005191

§ 371 Date: Oct. 7, 2024

(30) Foreign Application Priority Data
Feb. 16, 2022 (WO) PCT/JP2022/006209

(51) Int. Cl. H05K 3/18; G03F 1/38; H05K 1/02

(52) U.S. Cl. CPC H05K 3/188; G03F 1/38; H05K 1/0296; H05K 2201/09781; H05K 2203/0121; H05K 2203/0582; H05K 2203/0723

(57) ABSTRACT

Provided is a method for manufacturing a wiring substrate. The method includes forming a resist layer on a support body, exposing the resist layer, developing the exposed resist layer to form an opening in the resist layer, forming a metal wiring in the opening, and removing the resist layer after the metal wiring is formed. In the exposing of the resist layer, a wiring exposure pattern that corresponds to the metal wiring, and a dummy exposure pattern that does not correspond to the metal wiring are exposed to the resist layer. At least a part of the dummy exposure pattern is located in a region within 200 μm from an end portion of the wiring exposure pattern.

### TECHNICAL FIELD

The present disclosure relates to a method for manufacturing a wiring substrate, a wiring substrate, a reticle, and an exposure drawing data structure.

### BACKGROUND ART

A wiring substrate that forms an electronic device is required to have wirings with a minute width so as to cope with a demand for a reduction in size, a reduction in weight, and a high speed of the electronic device. As a method of forming the wiring with a minute width, a semi-additive process (SAP), and a modified semi-additive process (MSAP) have been widely used (for example, refer to Patent Literature 1). Typically, these processes include a process of forming a copper plating layer on a metal layer by electrolytic plating. As the metal layer, an electroless copper plating layer is used in the SAP method, and copper foil is used in the MSAP method.

### CITATION LIST

### Patent Literature

Patent Literature 1: Japanese Unexamined Patent Publication No. 2004-6773

### SUMMARY OF INVENTION

### Technical Problem

In recent, a wiring is becoming finer, terminal electrodes such as a bump and a via are becoming smaller in diameter in accordance with an increase in density of a semiconductor package. In a horizontal plane direction of the package, the wiring and the like are becoming finer and smaller by the SAP method or the like. On the other hand, the height of the wiring or the like in a vertical direction remains relatively high so as to keep a cross-sectional area of the wiring or the like at a certain level or greater from the viewpoint of electric resistance. Therefore, an aspect ratio of a metal wiring tends to increase, the metal wiring may collapse during a process of manufacturing the wiring substrate, and a yield ratio may deteriorate. On the other hand, it is known that a part of a dry film resist 130 that is widely used in a case of forming the metal wiring is stripped while swelling as illustrated in FIG. 11C and FIG. 11D in a resist striping process after forming a metal wiring 121 in an opening 135 by plating, as illustrated in FIGA. 11A to 11D. Due to swelling at the time of the striping, a stress is applied to the metal wiring 121 with a high aspect ratio as described above, and collapse of the metal wiring is further accelerated.

An object of the present disclosure is to provide a method for manufacturing a wiring substrate, a wiring substrate, a reticle, and an exposure drawing data structure which are capable of preventing from decreasing yield ratio due to collapse of a metal wiring.

### Solution to Problem

[1] An aspect of the present disclosure relates to a method for manufacturing a wiring substrate. The method for manufacturing a wiring substrate includes forming a resist layer on a support body, exposing the resist layer, developing the exposed resist layer to form an opening in the resist layer, forming a metal wiring in the opening, and removing the resist layer after the metal wiring is formed. In the exposing of the resist layer, a wiring exposure pattern that corresponds to the metal wiring, and a dummy exposure pattern that does not correspond to the metal wiring are exposed to the resist layer. At least a part of the dummy exposure pattern is located in a region within 200 μm from an end portion of the wiring exposure pattern.

In the above method for manufacturing a wiring substrate, at least a part of the dummy exposure pattern that does not form a wiring and the like in the wiring substrate is located in a region within 200 μm from an end portion of the wiring exposure pattern corresponding to the metal wiring that forms the wiring and the like in the wiring substrate. In this case, a stress from the resist to the metal wiring provided in a region exposed by the wiring exposure pattern can be reduced by providing a dummy metal structure in a region exposed by the dummy exposure pattern or by providing the dummy exposure pattern to make the resist layer in the region into a small piece. According to this, it is possible to prevent the metal wiring from collapsing due to a stress of the resist during the process of manufacturing the wiring substrate by the adjacent dummy exposure pattern. According to the method of manufacturing a wiring substrate, a decrease in yield ratio can be prevented. Note that, the metal wiring stated here includes, for example, a wiring electrode formed for electrical connection in a horizontal direction in a chip or substrate, or a terminal electrode or a protruding electrode formed for electrical connection in a vertical direction.

[2] In the method for manufacturing a wiring substrate according to [1], it is preferable that a part of the resist layer exposed by the dummy exposure pattern is fragmented and removed in the removing of the resist layer. Since the resist layer is fragmented into pieces in this case, a stress from the resist to the metal wiring provided in the region exposed by the wiring exposure pattern is reduced, and collapsing of the metal wiring such as the wiring electrode due to resist striping can be more reliably prevented, and a decrease in yield ratio can be prevented.

[3] In the method for manufacturing a wiring substrate according to [1] or [2], the dummy exposure pattern may include a mesh shape in which a plurality of lines are arranged in a lattice shape. In this case, the part of the resist layer exposed by the dummy exposure pattern is more reliably fragmented into pieces, and thus collapsing of the metal wiring such as the wiring electrode due to resist striping is more reliably prevented and a decrease in yield ratio can be prevented.

[4] In the method for manufacturing a wiring substrate according to any of [1] to [3], the dummy exposure pattern may include a dot shape in which a plurality of dots are arranged. In this case, the part of the resist layer exposed by the dummy exposure pattern is more reliably fragmented into pieces, and thus collapsing of the metal wiring such as the wiring electrode due to resist striping is more reliably prevented and a decrease in yield ratio can be prevented.

[5] In the method for manufacturing a wiring substrate according to any of [1] to [4], the dummy exposure pattern may include a linear part or a dot, and a width of the linear part or the dot is equal to or smaller than resolution of a resist that forms the resist layer. In this case, a dummy metal structure is not formed on the basis of the dummy exposure pattern. However, since the exposed resist layer is divided into small pieces, collapsing of the metal wiring can be prevented during resist striping. According to the manufacturing method, a decrease in yield ratio can be prevented. In addition, in this manufacturing method, since the dummy metal structure is less likely to be formed on the basis of the dummy exposure pattern, it is not necessary to leave unnecessary parts in the manufactured wiring substrate.

[6] In the method for manufacturing a wiring substrate according to any of [1] to [5], it is preferable that in the forming of the resist layer, the resist layer is formed on a metal layer provided on the support body, in the forming of the opening, the metal layer is exposed from the opening, and in the forming of the metal wiring, an electrolytic plating is deposited on the metal layer exposed in the opening to form the metal wiring. In this case, a finer wiring electrode and the like can be easily formed by forming the metal wiring with an SAP method or an MSAP method. Therefore, according to this method for manufacturing a wiring substrate, it is possible to realize a wiring electrode and the like which are fine or have a small diameter. In addition, in this manufacturing method, it is preferable that in a part of the resist layer exposed by the dummy exposure pattern, an opening from which the metal layer is exposed when being developed is not formed. In this case, since the opening from which the metal layer is exposed is not formed, the dummy metal structure is not formed on the basis of the dummy exposure pattern, and it is not necessary to leave unnecessary parts in the manufactured wiring substrate.

[7] In the method for manufacturing a wiring substrate according to any of [1] to [6], the dummy exposure pattern may be a pattern capable of exposing the resist layer so that a length of a long side of a fragmented striped resist piece becomes 100 μm or less. In this case, the resist layer is divided into small pieces, and thus a stress applied from the resist to the metal wiring provided in the region exposed by the wiring exposure pattern can be reduced. According to this, it is possible to prevent the metal wiring from collapsing due to a stress of the resist during the process of manufacturing the wiring substrate by the adjacent dummy exposure pattern. According to this method of manufacturing a wiring substrate, a decrease in yield ratio can be prevented.

[8] In the method for manufacturing a wiring substrate according to any of [1] to [7], the dummy exposure pattern may surround at least a part of the wiring exposure pattern. The dummy exposure pattern may surround the entirety of the wiring exposure pattern. Among a plurality of the metal wirings such as wiring electrodes formed to be arranged side by side, a metal wiring on an outer side tends to collapse due to the resist striping. However, due to the arrangement of the dummy exposure pattern, collapsing of the metal wirings can be more reliably prevented, and a decrease in yield ratio can be prevented.

[9] In the method for manufacturing a wiring substrate according to any of [1] to [8], the resist layer may be formed from a negative resist, and a swelling rate of the resist may be 30% by weight or less after immersion in a striping solution diluted 10 times at 22° C. for one minute. The swelling rate of the resist may be 5% by weight or more, or from 10% by weight to 20% by weight after immersion in a striping solution diluted 10 times at 22° C. for one minute. The striping solution can be a general-purpose striping solution.

[10] The method for manufacturing a wiring substrate according to any of [1] to [9], in the exposing of the resist layer, the resist layer may be exposed by using a reticle including the wiring exposure pattern and the dummy exposure pattern.

[11] In the method for manufacturing a wiring substrate according to any of [1] to [10], in the exposing of the resist layer, drawing is performed on the basis of exposure drawing data including the wiring exposure pattern and the dummy exposure pattern to expose the resist layer. Since a member such as a reticle is not necessary in this case, the manufacturing cost can be reduced accordingly. In addition, the exposure pattern can be easily created or modified by creating or modifying the exposure drawing data. Note that, in a case of performing exposure by using the exposure drawing data, for example, exposure can be performed by using a laser, beams of an electron gun, or the like.

[12] Another aspect of the present disclosure relates to a wiring substrate. The wiring substrate includes a support body, a plurality of metal wirings provided on the support body, and at least one dummy metal structure that surrounds at least a part of the plurality of metal wirings. A width or a diameter of the metal wiring in a short direction is 20 μm or less, and at least a part of the dummy metal structure is located in a region within 200 μm from a metal wiring closest to the dummy metal structure among the plurality of metal wirings. The dummy metal structure includes at least one among a mesh-shaped dummy metal structure in which a plurality of lines are arranged in a lattice shape, an inner dummy metal structure located between the plurality of metal wirings, and a dummy metal structure in which a plurality of dot-shaped electrodes are arranged to surround at least a part of the plurality of metal wirings. A planar shape of the dot-shaped electrodes may be, for example, a geometric pattern such as a circle, a triangle, a square, and an X-mark (cross-mark), and a combination thereof. In this case, it is possible to prevent the metal wiring from collapsing due to a stress caused by expansion of the resist during a process of manufacturing the wiring substrate by the adjacent dummy metal structure. According to the wiring substrate, collapsing of the metal wiring is prevented.

[13] As still another aspect of the present disclosure, there is provided a reticle for exposing a resist. The reticle includes a wiring exposure pattern, and a dummy exposure pattern in which at least a part is located within 200 μm from an end portion of the wiring exposure pattern. The dummy exposure pattern includes at least one among a mesh shape in which a plurality of lines are arranged in a lattice shape, and a dot shape in which a plurality of dots are arranged. When performing exposure by using the reticle, it is possible to locate at least a part of the dummy exposure pattern that does not form a wiring or the like in the wiring substrate in a region within 200 μm from an end portion of the wiring exposure pattern corresponding to the metal wiring that forms a wiring and the like in the wiring substrate, and it is possible to fragment a resist to be striped. According to this, it is possible to prevent the metal wiring from collapsing due to a stress caused by expansion of the resist during a processing of manufacturing the wiring substrate by an adjacent dummy exposure pattern (dummy metal structure), and it is possible to prevent a decrease in yield ratio of the wiring substrate.

[14] In the reticle according to [13], the dummy exposure pattern may be formed to surround at least a part or the entirety of the wiring exposure pattern. In this case, it is possible to more reliably prevent the metal wiring from collapsing due to the arrangement of the dummy exposure pattern, and it is possible to prevent a decrease in yield ratio of the wiring substrate.

[15] As still another aspect of the present disclosure, there is provided an exposure drawing data structure for an exposure apparatus to expose a resist layer. The exposure drawing data structure includes wiring exposure data configured to draw a wiring exposure pattern by the exposure apparatus, and dummy exposure data configure to draw a dummy exposure pattern by the exposure apparatus, at least a part of the dummy exposure pattern being located within 200 μm from an end portion of the wiring exposure pattern. The dummy exposure pattern includes at least one of a mesh shape in which a plurality of lines are arranged in a lattice shape, and a dot shape in which a plurality of dots are arranged. When performing exposure by using the exposure drawing data structure, it is possible to locate at least a part of the dummy exposure pattern that does not form a wiring electrode or the like in the wiring substrate in a region within 200 μm from an end portion of the wiring exposure pattern corresponding to the metal wiring that forms a wiring and the like in the wiring substrate. According to this, it is possible to prevent the metal wiring from collapsing during a processing of manufacturing the wiring substrate by an adjacent dummy exposure pattern, and it is possible to prevent a decrease in yield ratio of the wiring substrate.

### Advantageous Effects of Invention

According to the present disclosure, it is possible to prevent a decrease in yield ratio due to collapse of a metal wiring such as a wiring electrode.

### BRIEF DESCRIPTION OF DRAWINGS

FIGS. 1A to 1F are cross-sectional views illustrating an example of a method for manufacturing a wiring substrate according to an embodiment of the invention.

FIG. 2 is a plan view illustrating an example of a pattern that is exposed in an exposure process in the method for manufacturing a wiring substrate shown in FIGS. 1A to 1F.

FIG. 3 is an enlarged plan view illustrating a corner portion S of the exposure pattern shown in FIG. 2 in an enlarged manner.

FIGS. 4A to 4D are cross-sectional views illustrating an example of exposure and development of a region corresponding to a dummy exposure pattern, and illustrates an example of a case where a line width of the dummy exposure pattern is equal to or larger than resolution of a resist.

FIGS. 5A to 5D are cross-sectional views illustrating an example of exposure and development of a region corresponding to a dummy exposure pattern, and illustrates an example of a case where a line width of the dummy exposure pattern is smaller than resolution of a resist.

FIGS. 6A and 6B are views illustrating an example of an exposure pattern in which dummy exposure patterns are different from each other.

FIGS. 7A and 7B are views illustrating an example of an exposure pattern in which the dummy exposure patterns are further different from each other.

FIG. 8 is a view illustrating an exposure pattern according to Example 1.

FIG. 9 is a view illustrating an exposure pattern according to Comparative Example 1.

FIG. 10 is a photograph illustrating a wiring electrode of a wiring substrate according to Comparative Example 1.

FIGS. 11A to 11D are cross-sectional views illustrating a state in which a wiring electrode is inclined due to expansion of resist in a method for manufacturing a wiring substrate.

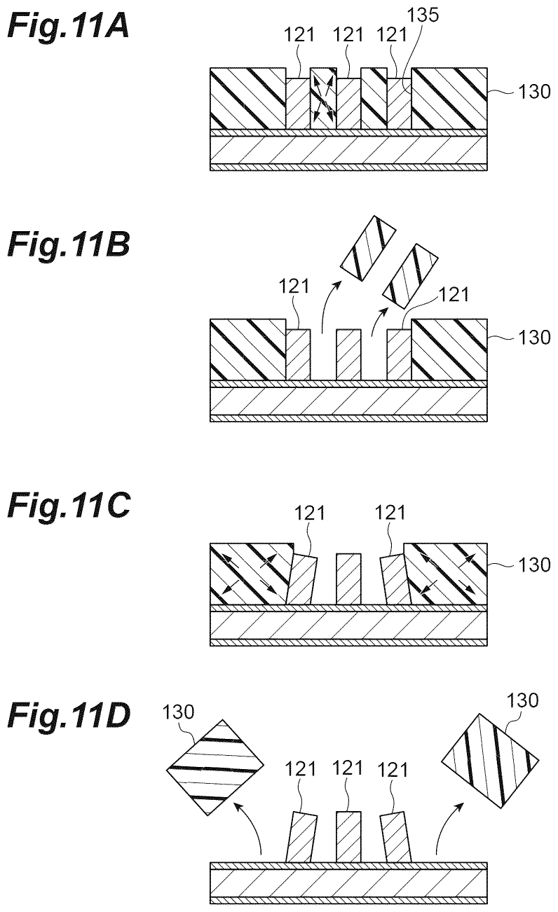

### DESCRIPTION OF EMBODIMENTS

Hereinafter, an embodiment according to the invention will be described in detail with reference to the accompanying drawings. In the following description, the same reference numeral will be given to the same or equivalent part, and redundant description thereof will be omitted. Positional relationships such as up, down, left, and right are based on positional relationships shown in the drawings unless otherwise stated. Dimensional ratios of the drawings are not limited to ratios shown in the drawings.

In this specification, a terminology such as “layer” includes not only a structure with a shape formed on an entire surface when being observed in a plan view, but also a structure with a shape formed only at a part of the surface. In this specification, a terminology of “process/step” includes not only an independent process/step, but also a process/step that can accomplish a predetermined operation even in a case where the process/step is not clearly distinguished from another process/step.

In this specification, a numerical value range indicated by using “to” represents a range including numeral values described before and after “to” as a minimum value and a maximum value, respectively. In a numerical value range described step by step in this specification, an upper limit value or a lower limit value of a numerical value range of any step may be substituted with an upper limit value or a lower limit value of a numerical value range of another step. In a numerical value range described in this specification, an upper limit value or a lower limit value of the numerical value range may be substituted with a value shown in an example.

In this specification, “(meth)acrylic acid” represents at least one of “acrylic acid” and “methacrylic acid” corresponding to “acrylic acid”, and this is also true of other similar expressions such as (meth)acrylate.

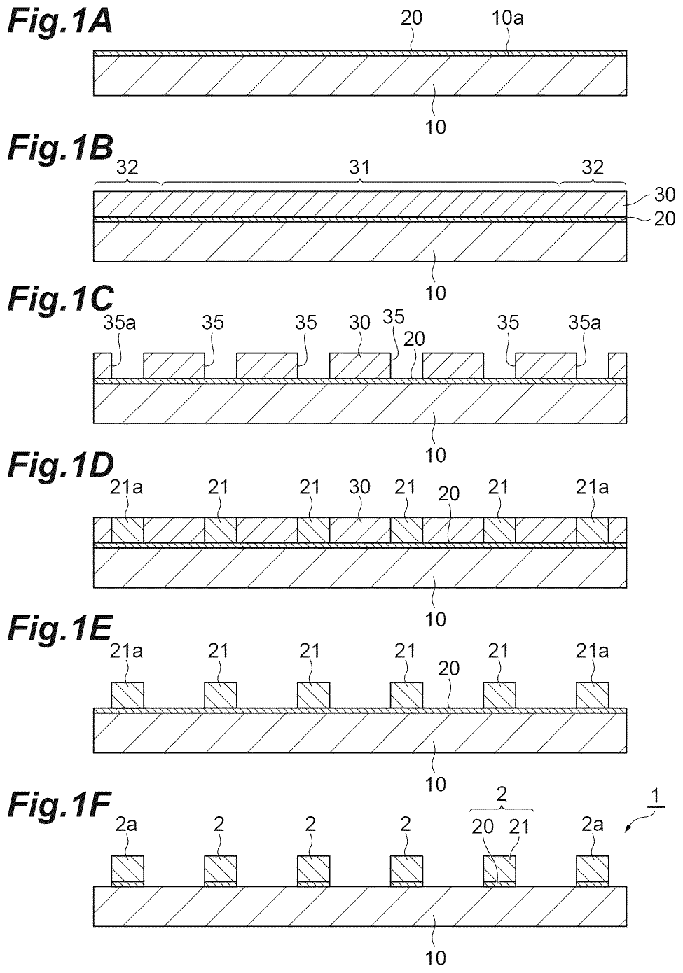

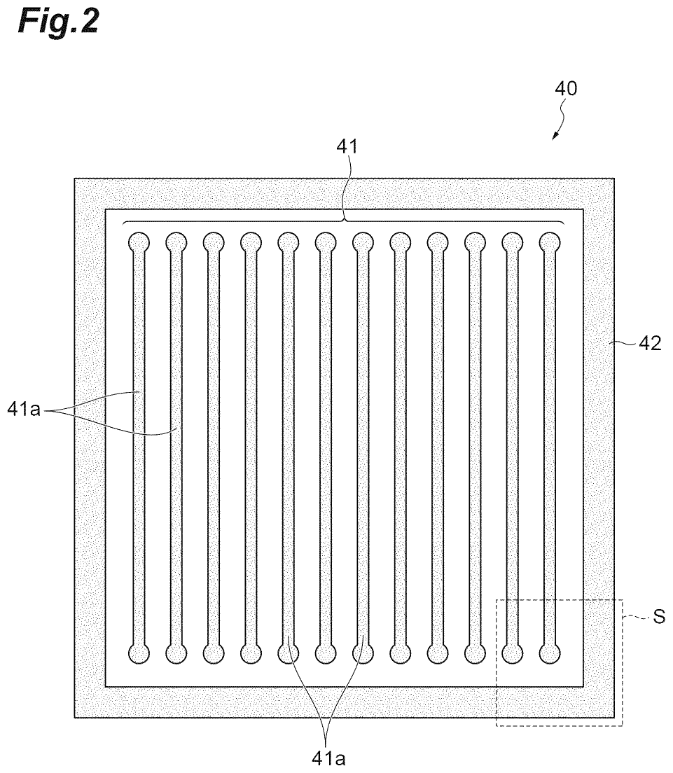

FIGS. 1A to 1F are views illustrating an example of a method for manufacturing a wiring substrate according to an embodiment of the invention. FIG. 2 is a plan view illustrating an example of a pattern that is exposed in an exposure process in the method for manufacturing a wiring substrate shown in FIGS. 1A to 1F. The method for manufacturing a wiring substrate shown in FIGS. 1A to 1F includes a process A of forming a metal layer on a support body, a process B of forming a resist layer on the metal layer on the support body, a process C of exposing the resist layer, a process D of developing the exposed resist layer to form an opening, a process E of forming a metal wiring in the opening, a process F of removing the resist layer after the metal wiring is formed, and a process G of removing a metal layer other than the metal wiring.

### [Process A]

In the process A, as shown in FIG. 1A, a metal layer 20 is formed on a main surface 10a of a plate-shaped support body 10. An outermost layer of the support body 10 on a side where the metal layer 20 is provided is, for example, an insulating layer. The insulating layer provided as the outermost layer of the support body 10 may be, for example, an insulating resin layer such as a build-up layer. The support body 10 may include a wiring that is connected to a wiring electrode 2 (refer to FIG. 1F) to be described later.

The metal layer 20 is a layer that functions as a seed layer for electrolytic plating. For example, the metal layer 20 may be a metal plating layer formed by electroless plating, metal foil such as copper foil, a layer formed by vapor deposition such as sputtering, or a metal sintered layer. The metal sintered layer is a layer that is formed by heating an applied film containing metal particles to sinter the metal particles. For example, the metal layer 20 may contain at least one kind of metal selected from the group consisting of copper, gold, silver, tungsten, molybdenum, tin, cobalt, chromium, iron, titanium, and zinc. The metal layer 20 may be a single layer, or may include two or more layers. The thickness of the metal layer 20 may be, for example, approximately 0.1 to 10.0 μm.

### [Process B]

In the process B, as shown in FIG. 1B, a resist layer 30 is formed on the metal layer 20 on the support body 10. The resist layer 30 can be formed by a photosensitive resist material that is typically used to form a wiring. The resist material that forms the resist layer 30 may be a negative resist material, or may be, for example, a material including an acrylic polymer containing a carboxylic acid. The thickness of the resist layer 30 may be, for example, 5 to 200 μm.

The resist material for forming the resist layer 30 may be, for example, a photosensitive resin composition containing a binder polymer, a photopolymerizable compound having an ethylenic unsaturated bond, and a photopolymerization initiator.

For example, the binder polymer may be a copolymer containing benzyl (meth)acrylate or a derivative thereof, styrene or a styrene derivative, an (meth)acrylic acid alkyl ester, and (meth)acrylic acid as monomer units.

Specific examples of the benzyl (meth)acrylate derivative constituting the binder polymer include 4-methylbenzyl (meth)acrylate, 4-ethylbenzyl (meth)acrylate, 4-tert-butylbenzyl (meth)acrylate, 4-methoxybenzyl (meth)acrylate, 4-ethoxybenzyl (meth)acrylate, 4-hydroxybenzyl (meth)acrylate, and 4-chlorobenzyl (meth)acrylate.

Specific examples of the styrene derivative constituting the binder polymer include vinyl toluene, p-methyl styrene, and p-chloro styrene.

The (meth)acrylic acid alkyl ester constituting the binder polymer may be an ester compound formed by (meth)acrylic acid, and a linear or branched aliphatic alcohol having 1 to 12 carbon atoms. The number of carbon atoms of the aliphatic alcohol may be 1 to 8 or 1 to 4. Specific examples of the (meth)acrylic acid alkyl ester include (meth)acrylic acid methyl, (meth)acrylic acid ethyl, (meth)acrylic acid propyl, (meth)acrylic acid isopropyl, (meth)acrylic acid butyl, (meth)acrylic acid tert-butyl, (meth)acrylic acid pentyl, (meth)acrylic acid hexyl, (meth)acrylic acid heptyl, (meth)acrylic acid octyl, and (meth)acrylic acid 2-ethylhexyl.

A proportion of a monomer unit derived from benzyl (meth)acrylate or a derivate thereof in the binder polymer may be 50 to 80% by mass, 50 to 75% by mass, 50 to 70% by mass, or 50 to 65% by mass on the basis of the mass of the binder polymer. A proportion of a monomer unit derived from styrene or a styrene derivate in the binder polymer may be 5 to 40% by mass or 5 to 35% by mass on the basis of the mass of the binder polymer. A proportion of a monomer unit derived from (meth)acrylic acid alkyl ester in the binder polymer may be 1 to 20% by mass, 1 to 15% by mass, 1 to 10% by mass, or 1 to 5% by mass on the basis of the mass of the binder polymer. A proportion of a monomer unit derived from (meth)acrylic acid in the binder polymer may be 5 to 30% by mass, 5 to 25% by mass, or 10 to 25% by mass on the basis of the mass of the binder polymer.

A weight-average molecular weight (Mw) of the binder polymer may be 20000 to 150000, 30000 to 100000, 40000 to 80000, or 40000 to 60000. The weight-average molecular weight stated here represents a standard polystyrene equivalent value obtained by gel permeation chromatography (GPC).

An acid value (mg KOH/g) of the binder polymer may be 13 to 78, 39 to 65, or 52 to 62. The acid value stated here represents the amount (mg) of potassium hydroxide required to neutralize 1 g of binder polymer.

Specific examples of the photopolymerizable compound having the ethylenic unsaturated bond include bisphenol A-based (meth)acrylate compounds, hydrogenated bisphenol A-based (meth)acrylate compounds, polyalkylene glycol (meth)acrylates, urethane monomers, pentaerythritol (meth)acrylates, and trimethylolpropane (meth)acrylates. These are used alone or in combination of two or more kinds. The bisphenol A-based di(meth)acrylate compounds may be, for example, a compound expressed by the following General Formula (1).

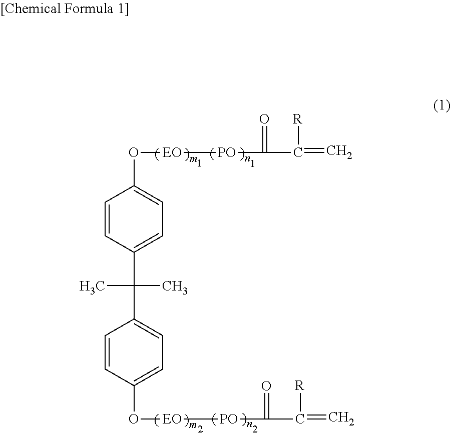

In Formula (1), R independently represents a hydrogen atom or a methyl group. EO and PO represent an oxyethylene group and an oxypropylene group, respectively. m₁, m₂, n₁, and n₂ independently represent 0 to 40, m₁+m₂ is 1 to 40, and n₁+n₂ is 0 to 20. Either EO or PO may be on a phenolic hydroxyl group side. m₁, m₂, n₁, and n₂ respectively represent the number of EO or PO. A compound in which m₁+m₂ is 5 or less on average, and a compound in which m₁+m₂ is 6 to 40 on average may be combined.

Polyalkylene glycol (meth)acrylate may be a compound expressed by the following Formula (2). As the photopolymerizable compound having an ethylenic unsaturated bond, a bisphenol A-based di(meth)acrylate compound, and a compound expressed by the following Formula (2) may be combined.

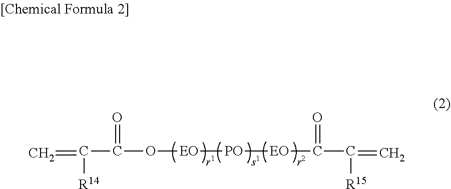

In Formula (2), R¹⁴ and R¹⁵ independently represent a hydrogen atom or a methyl group, respectively, EO and PO are as defined above, s¹ represents 1 to 30, r¹ and r² represent 0 to 30, respectively, and r¹+r² is 1 to 30. Examples of a commercially available product of the compound expressed by Formula (2) include a vinyl compound (manufactured by Showa Denko Materials Co., Ltd., product name: FA-023M) in which R¹⁴ and R¹⁵ are methyl groups, r¹+r² is 4 (average value), and s¹ is 12 (average value).

Specific examples of the photopolymerization initiator include aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butanone-1, and 2-methyl-1-[4-(methylthio)phenyl]-2-morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthrenequinone, 2-methyl-1,4-naphthoquinone, and 2,3-dimethylanthraquinone; benzoin ether compounds such as benzoin methyl ether, benzoin ethyl ether, and benzoin phenyl ether; benzoin compounds such as benzoin, methylbenzoin, and ethylbenzoin; benzyl derivatives such as benzyl dimethyl ketal; 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer; acridine derivatives such as 9-phenylacridine and 1,7-bis(9,9′-acridinyl) heptane, N-phenylglycine, N-phenylglycine derivatives, and coumarin-based compounds. These may be used alone or in combination of two or more kinds. The photopolymerization initiator may include a 2,4,5-triarylimidazole dimer, particularly, a 2-(O-chlorophenyl)-4,5-diphenylimidazole dimer.

The amount of the binder polymer contained in the photosensitive resin composition may be 40 to 80 parts by mass, 45 to 75 parts by mass, or 50 to 70 parts by mass with respect to 100 parts by mass of the total amount of the binder polymer and the photopolymerizable compound. The amount of the photopolymerization initiator contained in the photosensitive resin composition may be 0.01 to 5 parts by mass, 0.1 to 4.5 parts by mass, or 1 to 4 parts by mass with respect to 100 parts by mass of the total amount of the binder polymer and the photopolymerizable compound.

The photosensitive resin composition may contain other components as necessary. Examples of the other components include a photopolymerizable compound having a cationically polymerizable cyclic ether group, a cationic polymerization initiator, a sensitizer, a dye such malachite green, a photocolor former such as tribromomethylphenylsulfone and leuco crystal violet, a thermal coloring inhibitor, a plasticizer such as p-toluenesulfonamide, a pigment, a filler, a defoamer, a flame retardant, a stabilizer, an adhesion imparting agent, a leveling agent, a striping promoter, an antioxidant, a fragrance, an imaging agent, and a thermal crosslinking agent. The content of the other components may be 0.01 to 20 parts by mass with respect to 100 parts by mass of the total amount of the binder polymer and the photopolymerizable compound.

A total amount of the binder polymer, the photopolymerizable compound, and the photopolymerization initiator contained in the photosensitive resin composition may be 90 to 100% by mass or 95 to 100% by mass with respect to the total mass of components other than a solvent in the photopolymerizable resin compound.

To form the resist layer 30, a resist film containing the photosensitive resin composition may be laminated on the metal layer 20, or the photosensitive resin composition containing a solvent may be applied on the metal layer 20 and the solvent may be removed from the applied film.

The resist material (dry resist) that forms the resist layer 30 may swell when being striped by a striping solution. For example, a swelling rate of the resist material may be 30% by weight or less after immersion in a striping solution diluted 10 times at 22° C. for 1 minute. The swelling rate of the resist material may be 5% by weight or more or from 10% by weight to 20% by weight after immersion in a striping solution diluted 10 times at 22° C. for 1 minute. Note that, the striping solution can be a general-purpose striping solution.

The swelling rate of the resist material can be measured by using a quartz crystal microbalance (QCM) method. Specifically, the swelling rate can be measured, for example, by using QCM (IPN 603800 Rww.K, manufactured by INFICON) with a natural frequency of 5 MHz. First, the resist material that is a photosensitive film is laminated on the QCM under the same conditions as in an actual wiring forming process. Then, light irradiation is performed under the same conditions as in the actual wiring forming process. The resist material (film thickness: 25 μm) that is a sample after light irradiation is set in a QCM sensor, and is immersed in a beaker containing the following striping solution.

Striping solution: a solution obtained diluting a general-purpose striping solution (for example, 15 vol % of R-100S+8 vol % of R-101 (manufactured by MITSUBISHI GAS CHEMICAL COMPANY, INC.) 10 times

### Measurement Temperature: 22° C.

The frequency of the QCM crystal decreases as the resist swells, and thus a frequency variation Δf with respect to immersion time can be obtained as measurement data. Then, a weight variation (Δm) is calculated on the basis of the following Sauebrey Formula (1).

$$Δ f = Cf \times Δ m \qquad ( 1 )$$

Cf is a sensitivity factor of crystal that is used, and a unit thereof is Hz/ng/cm². In a case of employing a crystal of 5 MHz, Cf is 0.056. In this embodiment, a weight variation Δm/m (initial resist weight) after one minute from the start of measurement is defined as the swelling rate (%). Note that, for example, the swelling rate of a dry resist A (product name: RD1225, Showa Denko Materials Co., Ltd.) is 20%, and the swelling rate of a dry resist B (product name: RY5125, manufactured by Showa Denko Materials Co., Ltd.) is 15%. A dry resist of which the swelling rate is approximately 10% can be appropriately provided.

### [Process C]

In the process C, the resist layer 30 is exposed when formation of the resist layer 30 is terminated. In the process C, for example, a reticle (also, referred to as a photomask) is disposed on an upward side of the resist layer 30 to be an exposure pattern 40 having a configuration shown in FIG. 2, and predetermined exposure is performed. Due to the exposure, as illustrated in FIG. 2, the resist layer 30 is exposed in a wiring exposure pattern 41 (exposure pattern for wiring) corresponding to the wiring electrode 2 (metal wiring) and a dummy exposure pattern 42 that does not correspond to the wiring electrode. Note that, a resist part 31 exposed by the wiring exposure pattern 41 and a resist part 32 exposed by the dummy exposure pattern 42 are shown in FIG. 1B.

The wiring exposure pattern 41 is a part including a plurality of shielding portions 41a corresponding to a plurality of the wiring electrodes 2, respectively. The shielding portions 41a are regions which shield light emitted in a case of being exposed with light having a predetermined wavelength so as not to expose corresponding regions in the resist layer 30. When a part of the resist layer 30 is exposed in this manner, a resist layer 30 in which a reaction partially proceeds is formed. Exposure can be performed by a typical method known to those skilled in the art. In a case where the resist layer 30 is formed from a negative resist, an exposed portion is less soluble in a developer, and an exposed region remains after development. That is, a region for which exposure is shielded by the shielding portions 41a is dissolved by the developer.

The dummy exposure pattern 42 is an exposure pattern that is formed to surround the entirety of the wiring exposure pattern 41, and is formed to include a mesh shape in which a plurality of lines are arranged in a lattice shape. When the dummy exposure pattern 42 having the mesh shape is provided on an outer side of the wiring exposure pattern 41, the resist layer 30 on an outer side of the exposure pattern 41 can be divided into small parts. This allows striped pieces to be small (fragmented into pieces) in a resist striping process to be described later, and allows resist striping to be performed fast. Note that, the dummy exposure pattern 42 is not limited to the configuration shown in FIG. 2, and various aspects can be employed as described later.

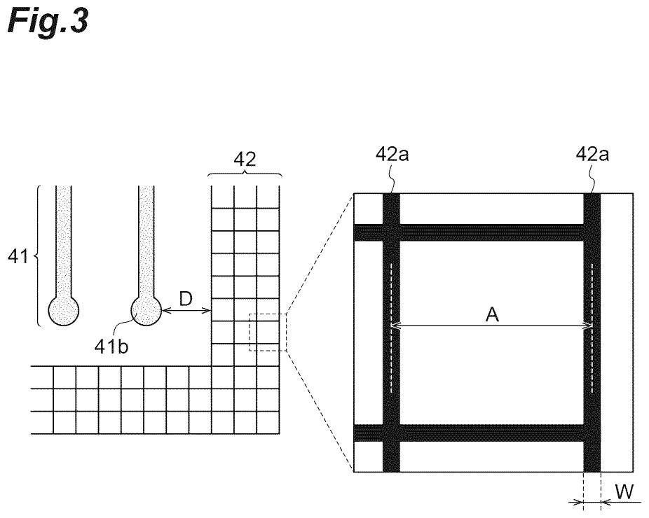

More specifically, as illustrated in FIG. 3, the dummy exposure pattern 42 is disposed close to an outer peripheral end portion 41b of the wiring exposure pattern 41, and a distance D between the outer peripheral end portion 41b of the wiring exposure pattern 41 and the dummy exposure pattern 42 (inner peripheral part) is within 200 μm. In other words, at least a part of the dummy exposure pattern 42 is located in a region within 200 μm from the end portion 41b of the wiring exposure pattern 41. The distance D between the wiring exposure pattern 41 and the dummy exposure pattern 42 may be, for example, 150 μm or less, 100 μm or less, or 50 μm or less. As an example, the distance D is 70 to 80 μm.

A separation distance A between linear parts 42a and 42a of the dummy exposure pattern 42 which form a mesh (a distance between both central lines) may be, for example, from 1 μm to 100 μm, from 1 μm to 75 μm, or from 1 μm to 50 μm. As an example, the separation distance A is 50 μm. A line width W of each of the linear parts 42a may be from 1 μm to 20 μm, from 1 μm to 10 μm, or from 1 μm to 5 μm. As an example, the line width W is 5 μm. When being exposed with light having a predetermined wavelength, the linear part 42a shields the emitted light as in the shielding portion 41a in order not to expose a corresponding region in the resist layer 30.

As described above, exposure in this embodiment may be exposure using a reticle that is a photomask, but an exposure pattern may be drawn on the resist layer 30 by a laser of an exposure apparatus or a beam of an electron gun on the basis of exposure data (exposure drawing data structure) including wiring exposure data corresponding to the wiring exposure pattern 41 and dummy exposure data corresponding to the dummy exposure pattern 42.

### [Process D]

In the process D, as illustrated in FIG. 1C, the exposed resist layer 30 is developed to form a plurality of openings 35 and 35a in the resist layer 30. The opening 35 is a part corresponding to the wiring electrode 2 in the wiring substrate 1, and the opening 35a is a part corresponding to the dummy metal structure 2a in the wiring substrate 1. In the development process, after exposure in the process C, the resist layer 30 is left for predetermined time (for example, 30 minutes), a protective film of the resist film is striped, and a development treatment is performed, for example, by using 1.0% aqueous sodium carbonate solution. According to this, a part that is not exposed is dissolved, and the openings 35 and 35a are formed. In a case where the openings 35 and 35a are formed, the metal layer 20 serving as a seed layer in a plating treatment is exposed in the openings 35 and 35a. For example, the openings 35 and 35a are recessed portions having a width of approximately 5 μm in a short direction, and extend in a direction orthogonal to the paper surface. The openings 35 and 35a may have the same size, a width or a diameter of the opening 35a may be larger than that of the opening 35, or the width or diameter of the opening 35a may be smaller than that of the opening 35.

When the exposed resist layer 30 is developed as described above, the resist layer 30 including the openings 35 and 35a from which the metal layer 20 is exposed is formed. The development can be performed by a typical method known to those skilled in the art. A developing solution for development may be an alkali aqueous solution like the aqueous sodium carbonate solution.

Note that, as described later, in a case where the line width of the dummy exposure pattern 42 is equal to or smaller than resolution of the resist, the opening 35a formed by development is not complete, and the metal layer 20 is not exposed in the opening 35a. In this case, although the dummy metal structure 2a is not formed at a location corresponding to 35a in the subsequent process, a solution penetrates from a linear part of the dummy exposure pattern 42 that is not exposed during the striping process, and the resist layer 30 is easily fragmented into small pieces the dummy part set as a boundary. That is, a part corresponding to the opening 35a becomes a resist part that is easily fragmented into small pieces during the subsequent striping process. According to this, the resist is fragmented into pieces during striping, and thus a stress applied to the wiring decreases, and a yield ratio can be improved even though the dummy metal structure is not formed. In addition, when the dummy pattern is provided, penetration of a solution becomes fast, and thus this leads to shortening of striping process time.

### [Process E]

In the process E, as illustrated in FIG. 1D, metal layers 21 and 21a are formed by electrolytic plating by using the metal layer 20 exposed in a plurality of the openings 35 and 35a as a seed layer, and the wiring electrode 2 and the dummy metal structure 2a are formed in the plurality of openings 35 and 35a. In this process, for example, the openings 35 and 35a are filled by copper plating. A method for forming the metal layer 21 may be electrolytic plating, electroless plating, injection and sintering of metal-containing paste, and a combination thereof.

A metal that forms the metal layer 21 may include, for example, at least one metal selected from the group consisting of copper, gold, silver, nickel, tin, titanium, tungsten, molybdenum, cobalt, chromium, iron, and zinc. The metal layers 21 and 21a may be a single layer or may be configured by two or more layers. The thickness of the metal layers 21 and 21a may be, for example, 0.1 to 10.0 μm, or 1 to 150 μm.

The metal layers 21 and 21a may include a linear part, and a width thereof may be 1 to 20 μm. In other words, a line/space (L/S) of the wiring electrode 2 and the dummy metal structure 2a including the metal layers 21 and 21a may be 1 μm/1 μm to 20 μm/20 μm. According to the method of this embodiment, since the exposure pattern including the dummy exposure pattern 42 is exposed, there is little possibility that defects such as striping and collapsing of the wiring occur even in a fine wiring.

The metal layers 21 and 21a may include a circular portion, a diameter thereof may be 5 to 100 μm or 20 μm or less. According to the method of this embodiment, since the exposure pattern including the dummy exposure pattern 42 is exposed, there is little possibility that defects such as striping and collapsing of the wiring occur even in a fine wiring. As described above, in a case where the line width of the dummy exposure pattern 42 is equal to or smaller than the resolution of the resist, and the opening 35a is not completely formed, the metal layer 21a and the dummy metal structure 2a are also not formed.

### [Process F]

In the process F, when formation of the metal layers 21 and 21a in the openings 35 and 35a is terminated, as illustrated in FIG. 1E, the resist layer 30 is striped form the metal layer 20. The striping is performed by using a striping solution that is typically used. Examples of a general-purpose striping solution are as described above.

### [Process G]

In the process G, as illustrated in FIG. 1F, the metal layer 20 in a part exposed by striping of the resist layer 30, that is, a part excluding regions bonded to the metal layers 21 and 21a is removed by a method such as etching. According to this, the wiring electrode 2 including the metal layers 20 and 21 remained on the support body 10 is formed, and the dummy metal structure 2a including the metal layer 20 and the metal layer 21a is formed. Since the dummy metal structure 2a is a member for preventing collapsing of the wiring electrode 2 due to the resist, it is preferable that the dummy metal structure 2a is electrically insulated from another electrode (for example, the wiring electrode 2, an electrode in the support body 10, or the like).

Through the process, as illustrated in FIG. 1F, the wiring substrate 1 including the support body 10, and a plurality of the wiring electrodes 2 provided on the support body 10, and a plurality of the dummy metal structures 2a can be obtained. The dummy metal structures 2a are formed to surround the plurality of wiring electrodes 2 as in the dummy exposure pattern 42, and at least a part of the dummy metal structure 2a is located in a region within 200 μm from a wiring electrode, which is closest to the dummy metal structures 2a, among the plurality of wiring electrodes 2. The wiring substrate 1 may have a configuration in which the dummy metal structures 2a prepared based on the dummy exposure pattern 42 are not formed. This will be described below.

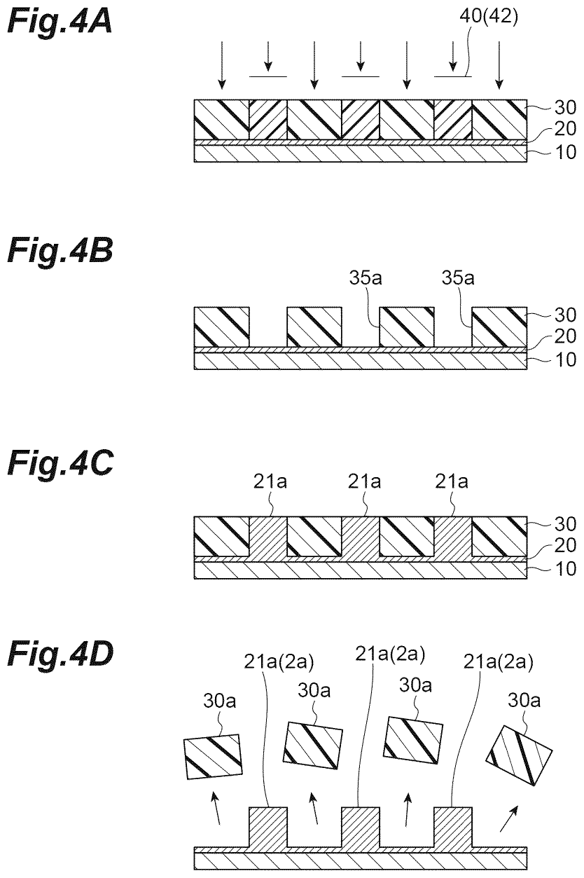

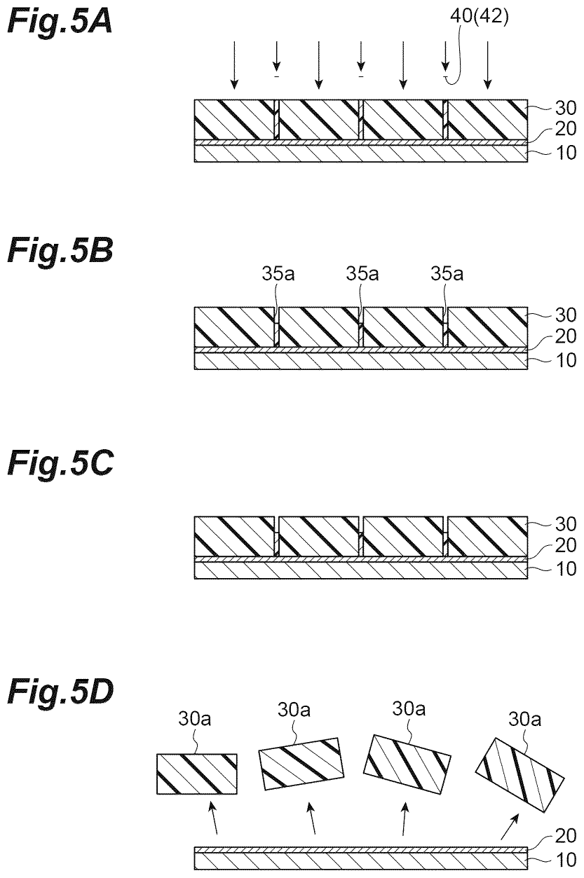

The exposure process in the process C to the electrode forming process in the process E will be described in more detail with reference to FIGS. 4A to 4D and FIGS. 5A to 5D. FIGS. 4A to 4D are cross-sectional views illustrating an example of exposure and development of a region corresponding to the dummy exposure pattern, and illustrates an example in a case where the width of the dummy exposure pattern is equal to or larger than the resolution of the resist. The method illustrated in FIGS. 4A to 4D is similar to the above-described method. FIGS. 5A to 5D are cross-sectional views illustrating an example of exposure and development of a region corresponding to the dummy exposure pattern and illustrates an example of a case where the width of the dummy exposure pattern is smaller than the resolution of the resist. Hereinafter, description will be mainly given of a manufacturing method in an exposure part by the dummy exposure pattern 42, and a manufacturing method in an exposure part by the wiring exposure pattern 41 is as described above, and thus description thereof will be omitted.

In a case where the line width W of the dummy exposure pattern 42 (linear part 42a) is equal to or larger than the resolution of the resist that forms the resist layer 30, subsequently to the process A and the process B, first, the resist layer 30 is exposed by employing the dummy exposure pattern 42 with a wide width as illustrated in FIG. 4A (process C). Then, as illustrated in FIGS. 4B and 4C, a development process in the process D, an electrode forming process in the process E are performed to form the metal layer 21a for the dummy metal structure 2a.

Then, as illustrated in FIG. 4D, in a resist striping process of the process F, the resist layer 30 on an outer side of the metal layer 21a for the dummy metal structure 2a is striped. At the time of the striping, the resist layer 30 is fragmented into resist pieces 30a and is removed. In this case, the wiring electrode 2 that is close to the dummy metal structure 2a is protected from a stress caused by expansion of the resist of the resist layer 30 due to the dummy metal structure 2a, and is prevented from being inclined or collapsing. Since the resist layer 30 itself becomes small pieces, the stress due to expansion of the resist is decreased, and thus in this regard, the wiring electrode 2 is also prevented from being inclined or collapsing.

On the other hand, in a case where the width of the dummy exposure pattern 42 is smaller than the resolution of the resist that forms the resist layer 30, subsequently to the process A and the process B, first, as illustrated in FIG. 5A, the resist layer 30 is exposed by employing the dummy exposure pattern 42 having a narrow width (process C). Then, as illustrated in FIG. 5B, a development process of the process D is performed. At this time, since the line width W of the linear part 42a of the dummy exposure pattern 42 is smaller than the resolution of the resist, the opening 35a that is formed with development by a developing solution is not complete, and the metal layer 20 is not exposed in the opening 35a. Since the metal layer 20 is not exposed, as illustrated in FIG. 5C, the dummy metal structure is not formed in an electrode forming process in the process E.

Then, as illustrated in FIG. 5D, in a resist striping process in the process F, the resist layer 30 is striped. At the time of the striping, the resist layer 30 is fragmented into fine resist pieces 30a and is striped. The lengths of a short side and a long side of the fragmented striped resist pieces are preferably from 1 μm to 100 μm, from 1 μm to 75 μm, and may be from 1 μm to 50 μm. That is, the dummy exposure pattern 42 that is used in the exposure pattern is a pattern capable of exposing the resist layer 30 so that the length of either the long side or the short side of the fragmented striped resist pieces is 100 μm or less, 75 μm or less, or 50 μm or less. In this case, in the wiring electrode 2 close to the dummy region 42a formed by the dummy exposure pattern 42, since the resist layer 30 at the periphery of the wiring electrode 2 becomes small pieces, a stress caused by expansion of the resist decreases, the wiring electrode 2 is prevented from being inclined or collapsing even when the dummy metal structure 2a is not provided. Even when the metal layer 20 is not exposed in the dummy region 42a, since curing of the dummy region 42a is weaker as compared with an exposed part, the striping solution is likely to penetrate into the corresponding portion, and resist is striped while being fragmented into small pieces. Accordingly, the stress mitigation effect during striping as described above can be sufficiently obtained. In a case where the metal layer 20 is not exposed in the dummy region 42a, plating is not deposited to the dummy region 42a, and plating is deposited only to the wiring portion that is necessary for the wiring substrate to form the wiring electrode 2. That is, in this case, it is possible to obtain a wiring substrate that is not provided with the dummy metal structure 2a shown in FIG. 1F. The fragmented striped resist pieces in a case shown in FIGS. 4A to 4D may have the same length as in the striped resist pieces in a case shown in FIGS. 5A to 5D, and the dummy exposure pattern 42 in FIGS. 4A to 4D is also set to realize the striped resist pieces.

As described above, in the method for manufacturing a wiring substrate according to this embodiment, at least a part of the dummy exposure pattern 42 that does not form the wiring electrode 2 is located in a region within 200 μm from the end portion 41b of the wiring exposure pattern 41 corresponding to the wiring electrode 2 forming the wiring and the like in the wiring substrate 1. In this case, when the dummy metal structure 2a is provided in a region exposed by the dummy exposure pattern 42 or the dummy exposure pattern 42 is provided, the resist layer 30 in the region is fragmented into small pieces, thereby decreasing a stress applied to the wiring electrode 2 from the resist. According to this, it is possible to prevent the wiring electrode 2 from collapsing due to a stress of the resist during the process of manufacturing the wiring substrate 1 by the adjacent dummy exposure pattern 42 (or the dummy metal structure 2a). According to the method of manufacturing a wiring substrate, it is possible to prevent a decrease in yield ratio.

In the method for manufacturing a wiring substrate according to this embodiment, a part of the resist layer 30 exposed by the dummy exposure pattern 42 is fragmented into pieces and removed in a process of removing the resist layer 30. In this manner, since the resist layer 30 is fragmented into pieces, a stress applied to the wiring electrode 2 provided in the region exposed by the wiring exposure pattern 41 from the resist is decreased, and thus collapsing of the wiring electrode 2 due to resist striping can be more reliably prevented, and a decrease in yield ratio can be prevented.

In the method of manufacturing a wiring substrate according to this embodiment, the dummy exposure pattern 42 may include a mesh shape in which a plurality of lines are arranged in a lattice shape. In this case, the part of the resist layer 30 exposed by the dummy exposure pattern 42 is more reliably fragmented into pieces, and thus collapsing of the metal wiring such as the wiring electrode due to resist striping is more reliably prevented and a decrease in yield ratio can be prevented.

In the method for manufacturing a wiring substrate according to this embodiment, the dummy exposure pattern 42 may include the linear part 42a, and the line width W of the linear part 42a may be equal to or smaller than resolution of a resist that forms the resist layer 30. In this case, a dummy metal structure is not formed on the basis of the dummy exposure pattern 42, but since the exposed resist layer 30 is divided into small pieces, collapsing of the wiring electrode 2 can be prevented during resist striping. According to the manufacturing method, a decrease in yield ratio can be prevented. In the manufacturing method, the dummy metal structure is less likely to be formed on the basis of the dummy exposure pattern 42, it is not necessary to leave unnecessary parts in the manufactured wiring substrate 1.

In the method for manufacturing a wiring substrate according to this embodiment, in the process of forming the resist layer 30, the resist layer 30 is formed on the metal layer 20 provided on the support body 10, in the process of forming the opening, the metal layer 20 is exposed from the opening 35, and in the process of forming the wiring, an electrolytic plating is deposited on the metal layer 20 exposed in the opening 35 to form the wiring electrode 2. In this case, a finer wiring electrode 2 can be easily formed by forming the metal wiring by the SAP method, the MSAP method or the like. According to the method for manufacturing a wiring substrate, it is possible to realize a wiring electrode which are fine or have a small diameter. In the manufacturing method, an opening from which the metal layer is exposed when being developed may not be formed in a part of the resist layer 30 exposed by the dummy exposure pattern 42. In this case, since the opening from which the metal layer is exposed is not formed, the dummy metal structure is not formed on the basis of the dummy exposure pattern 42, and it is not necessary to leave unnecessary parts in the manufactured wiring substrate.

In the method for manufacturing a wiring substrate according to this embodiment, the dummy exposure pattern 42 may be a pattern capable of exposing the resist layer 30 so that a length of a long side of a fragmented striped resist piece becomes 100 μm or less. In this case, the resist layer 30 is divided into small pieces, and thus a stress applied from the resist to the metal wiring provided in the region exposed by the wiring exposure pattern 41 can be reduced. According to this, it is possible to prevent the metal wiring from collapsing due to a stress of the resist during the process of manufacturing the wiring substrate by the adjacent dummy exposure pattern 42. According to the method of manufacturing a wiring substrate, a decrease in yield ratio can be prevented.

In the method for manufacturing a wiring substrate according to this embodiment, the dummy exposure pattern 42 surrounds the entirety or a part of the wiring exposure pattern 41. An outer side part of the wiring electrode 2 tends to collapse due to resist striping. Since the dummy exposure pattern 42 is disposed in this manner, collapsing of the wiring electrode 2 is more reliably prevented, and a decrease in yield ratio can be prevented.

In the method for manufacturing a wiring substrate according to this embodiment, the width or the diameter of the wiring electrode 2 in a short direction may be 20 μm or less. In this case, the wiring electrode 2 and the like can be made finer or more minute. Thus, even in a case where the fine or minute wiring electrode is provided, collapsing of the wiring electrode is prevented and thus a decrease in yield ratio can be prevented.

In the method of manufacturing a wiring substrate according to this embodiment, in the process of exposing the resist layer 30, the resist layer 30 is exposed by using a reticle including the wiring exposure pattern 41 and the dummy exposure pattern 42. In this case, time required for each exposure process can be reduced, and thus it is possible to improve manufacturing efficiency of the wiring substrate 1. In addition, it is possible to reduce a deviation between respective exposure processes, and thus it is possible to improve a yield ratio of the wiring substrate 1.

In the method for manufacturing a wiring substrate according to this embodiment, in the process of exposing the resist layer 30, the resist layer 30 may be exposed by drawing on the basis of exposure drawing data including the wiring exposure pattern 41 and the dummy exposure pattern 42. In this case, since a member such as a reticle is not necessary, the manufacturing cost can be reduced accordingly. In addition, the exposure pattern can be easily created or modified by creating or modifying the exposure drawing data.

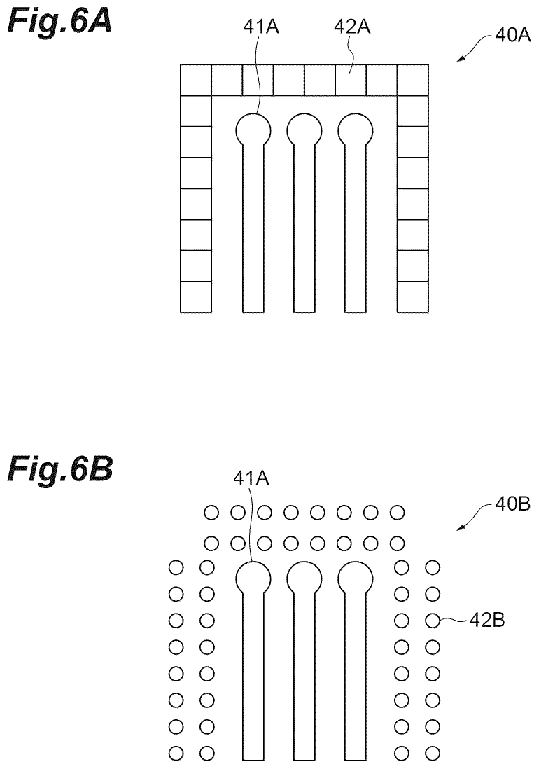

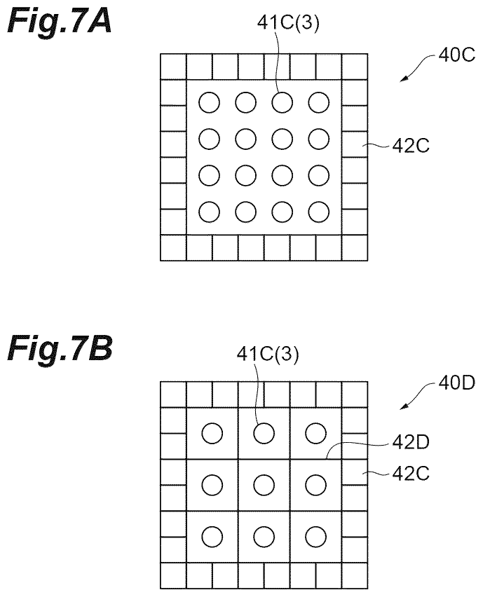

Hereinbefore, description has been given of the embodiment of the present disclosure, but the invention is not limited to the embodiment, and appropriate modifications can be made within a range not departing from the gist of the invention. For example, the exposure pattern 40 may be an exposure pattern having each configuration illustrated in FIGS. 6A, 6B and FIGS. 7A, 7B. As illustrated in FIG. 6A, an exposure pattern 40A may be used as the exposure pattern. The exposure pattern 40A includes a dummy exposure pattern 42A that surrounds a part (three directions in the example in the drawing) of a wiring exposure pattern 41A corresponding to the linear wiring electrode 2. The dummy exposure pattern 42A may have a mesh shape. Even in this case, at least a part of the dummy exposure pattern 42A is located in a region within 200 μm from an end portion of the wiring exposure pattern 41A corresponding to the wiring electrode 2. Thus, a part of the resist layer 30 exposed by the dummy exposure pattern 42A is fragmented into pieces and removed in a process of removing the resist layer 30. According to this, collapsing of the wiring electrode 2 is prevented. This is also true of the following modification example.

As illustrated in FIG. 6B, an exposure pattern 40B may be used as the exposure pattern. The exposure pattern 40B includes a dummy exposure pattern 42B that surrounds a part (three directions in the example in the drawing) of a wiring exposure pattern 41A corresponding to the linear wiring electrode 2. The dummy exposure pattern 42B is provided with a plurality of dot-shaped light-shielding portions and is formed to cover a part of the wiring exposure pattern 41A. In a plan view, the dot-shaped light-shielding portion shows a geometric pattern such as a circle shape, a triangular shape, a square shape, an X-mark, and a combination thereof. In this way, various patterns can be used as the dummy exposure pattern, and various patterns can be employed as long as a resist of the resist layer 30 can be stripped fast, or a striped piece can be made small. Even in this case, at least a part of the dummy exposure pattern 42B is located in a region within 200 μm from an end portion of the wiring exposure pattern 41A corresponding to the wiring electrode 2. Thus a part of the resist layer 30 exposed by the dummy exposure pattern 42B is fragmented into pieces and is removed in a process of removing the resist layer 30. Note that, the wiring electrode 2 stated here is a wiring electrode that is formed for electrical connection, for example, in a horizontal direction in a chip or a substrate as described above.

As illustrated in FIG. 7A, an exposure pattern 40C provided with a dummy exposure pattern 42C to surround the entirety of a terminal exposure pattern 41C (wiring exposure pattern) corresponding to a circular terminal electrode 3 (metal wiring) may be employed. The dummy exposure pattern 42C is configured to surround the terminal exposure pattern 41C doubly. As illustrated in FIG. 7B, an exposure pattern 40D may be used as the exposure pattern. The exposure pattern 40D has a configuration in which an inner dummy exposure pattern 42D (corresponding to an inner dummy metal structure) is located between a plurality of the terminal electrodes 3, in addition to the configuration of the dummy exposure pattern 42C. In this case, a pitch between the terminal electrodes 3 may be widened. Note that, the terminal electrodes 3 stated here are, for example, terminal electrodes formed for electrical connection in a vertical direction. For example, the terminal electrodes 3 may be protruding electrodes formed for electrical connection in a vertical direction. Even in this modification example, at least a part of the dummy exposure pattern 42C or the inner dummy exposure pattern 42D is located in a region within 200 μm from an end portion of the terminal exposure pattern 41C corresponding to the wiring electrode 2. Thus a part of the resist layer 30 exposed by the dummy exposure pattern 42C or the inner dummy exposure pattern 42D is fragmented into pieces and removed in a process of removing the resist layer 30.

### EXAMPLES

Hereinafter, the invention will be described in more detail with reference to examples. However, the invention is not limited to the examples.

### [Preparation of Mask]

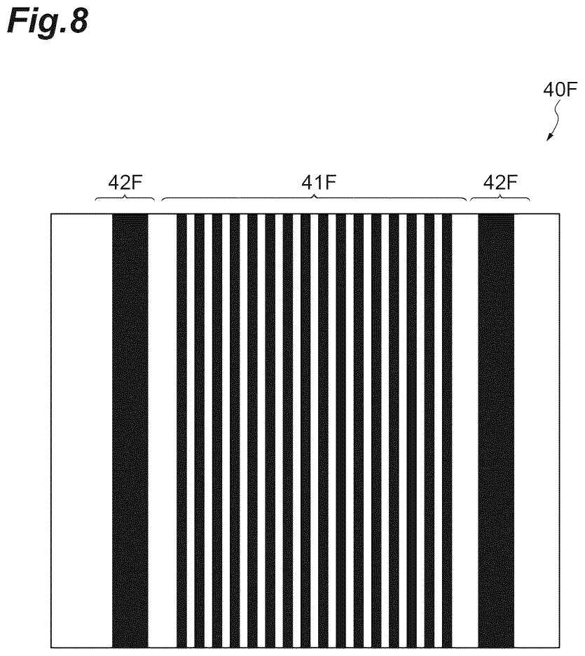

As Example 1, a reticle 40F including a Cr-shielding portion was prepared (refer to FIG. 8). A design pattern of the reticle was set to have a linear wiring structure with line/space (L/S) of 5 μm/5 μm (wiring exposure pattern 41F). In addition, the design pattern was set to a design including a dummy wiring with a line width of 30 μm on an outer side of the fine wiring (dummy exposure pattern 42F). The closest distance D (refer to FIG. 3) between the dummy exposure pattern 42F and the wiring exposure pattern 41F was 20 μm.

### [Formation of Wiring Layer]

### [Formation of Resist Layer]

A negative resist film (manufactured by Showa Denko Materials Co., Ltd., thickness: 25 μm) was laminated on a copper-clad laminate (manufactured by Showa Denko Materials Co., Ltd.) for printed circuit board having a square of 150 mm, and a thickness of 0.81 mm by using a laminator (GK-13DX, manufactured by Lami Corporation Inc.). A lamination temperature was set to 110° C., a lamination rate was set to 1.4 m/minute, and a lamination pressure was set to 0.5 MPa. After lamination, the resultant body was left for 30 minutes, and the resist film was exposed by using an i-ray stepper (S6Ck, manufactured by CERMA PRECISION, INC.) and a negative photomask. Illuminance was set to 33 mW/cm², and an exposure dose was set to 120 mJ/cm². As the negative photomask, the above-described photomask was used. As the resist film, a resist film of which a swelling rate after immersion in a striping solution (to be described later) diluted 10 times at 22° C. for 1 minute is 15% by weight or less was employed.

After exposure, the resist film was left for 60 minutes, a protective film of the resist film was striped, and a resist layer was formed by development using 1.0% aqueous sodium carbonate solution. This resist layer includes a linear pattern having a line/space (L/S) of 5 μm/5 μm from which a seed layer is exposed, and a dummy linear pattern having a line width of 30 μm on an outer side of the fine wiring. The development was performed by spraying a development liquid for 260 seconds by using an ultrahigh pressure spin development apparatus (manufactured by Blue Ocean Technology., Ltd.) and then by spraying pure water as a rinse solution for 100 seconds. A development temperature was set to 30° C., the number of revolutions was set to 500 rpm, a spray pressure was set to 0.18 MPa, a movement distance of a spray nozzle head was set to 7.2 cm, and a movement speed of the spray nozzle head was set to 10 cm/s.

### [Cleaner Preliminary Treatment]

A substrate on which the seed layer and the resist layer were formed was immersed in 100 mL/L aqueous solution of an acidic cleaner (PB-242D, manufactured by JCU CORPORATION) at 45° C. for 5 minutes. Then, the substrate on which the seed layer and the resist layer were formed was sequentially immersed in pure water kept at 50° C. for 1 minute, pure water kept at 25° C. for 1 minute, and 10% aqueous sulfuric acid solution kept at 25° C. for 1 minute.

### [Cu Electrolytic Plating]

Then, the copper-clad laminate with the resist layer after the acid cleaning treatment was immersed in an electrolytic copper plating solution. This electrolytic copper plating was performed at 25° C. for 10 minutes. As the electrolytic copper plating solution, a mixed solution was used. This mixed solution includes 120 g/L of copper sulfate pentahydrate, 7.3 L of an aqueous solution of 220 g/L of 96% sulfuric acid, 0.26 mL of hydrochloric acid, 92 mL of Top Lucina NSV-1 (product name, manufactured by OKUNO Chemical Industries Co., Ltd.), 11.5 mL of Top Lucina NSV-2 (product name, manufactured by OKUNO Chemical Industries Co., Ltd.), and 23 mL of Top Lucina NSV-3 (product name, manufactured by OKUNO Chemical Industries Co., Ltd.).

### [Resist Striping]

The resist layer existing on the substrate after being subjected to the electrolytic plating treatment was striped to form a substrate including copper wirings. The striping was performed by spraying a striping solution for 300 seconds by using a photolithography developing apparatus AD-3000 (manufactured by Takizawa Sangyo Co., Ltd.), and then by spraying pure water as a rinse liquid for 30 seconds. A striping temperature was set to 50° C., the number of revolutions was set to 500 rpm, a spray pressure was set to 0.18 MPa, a movement distance of a spray nozzle head was set to 7.2 cm, and a movement speed of the spray nozzle head was set to 10 cm/s. As the striping solution, a mixed solution of 150 mL/L of A-06A (product name, manufactured by Kao Corporation) and 80 mL/L of A-06B (product name, manufactured by Kao Corporation) was used.

### Comparative Example 1

### [Preparation of Mask]

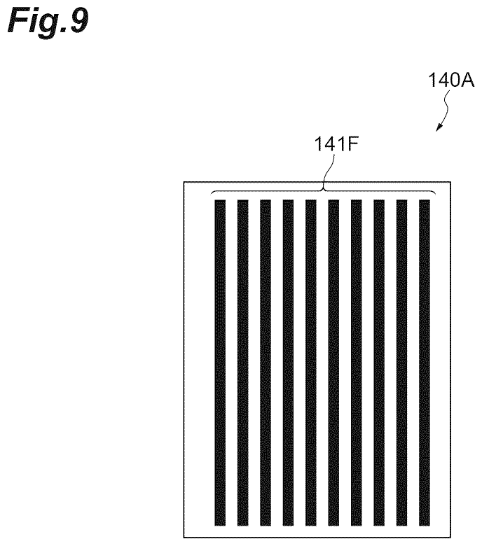

In Comparative Example 1, a reticle 140A including a Cr-shielding portion was prepared. A design was set to have a linear wiring structure with line/space (L/S) of 5 μm/5 μm (wiring exposure pattern 141F) as illustrated in FIG. 9. In the reticle 140A shown in FIG. 9, a dummy pattern was not formed.

### [Formation of Wiring Layer]

Formation of a resist layer, a cleaner preliminary treatment, formation of Cu electrolytic plating, and resist striping were performed under the same conditions as in Example 1, except for the design of the reticle that was used.

### [Evaluation of Collapsing Observation]

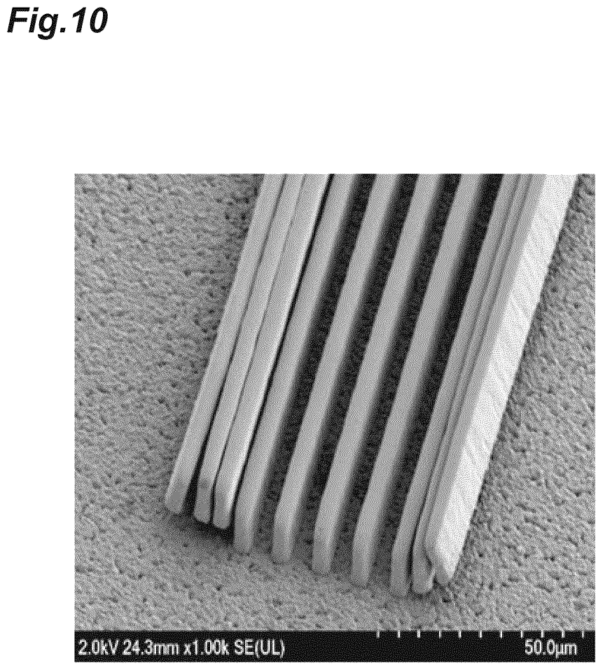

The formed copper wiring was observed by using an optical microscope. The number of wirings for which collapsing was observed, and a ratio of collapsed wirings to the number of designed wirings are summarized in Table 1. A photograph of the wiring electrode according to Comparative Example 1 is shown in FIG. 10.

TABLE 1

| | | Comparative |
|---|---|---|
| | Example 1 | Example 1 |
| Number of collapsing | 0/24 | 5/10 |
| (pieces) | | |
| Collapsing ratio (%) | 0 | 50 |

As described above, as shown in Table 1, it was confirmed that when the dummy exposure pattern adjacent to the wiring exposure pattern is included in the exposure design pattern, collapsing of the plating pattern with a high aspect ratio can be prevented, and a yield ratio can be improved.

### REFERENCE SIGNS LIST

1: wiring substrate, 2: wiring electrode, 2a: dummy metal structure, 3: terminal electrode, 10: support body, 20: metal layer, 30: resist layer, 35, 35a: opening, 40, 40A, 40B, 40C, 40D: exposure pattern, 40F: reticle, 41, 41A: wiring exposure pattern, 41C: terminal exposure pattern, 41b: end portion, 42, 42A, 42B, 42C, 42D: dummy exposure pattern.

1. A method for manufacturing a wiring substrate, comprising:
forming a resist layer on a support body;
exposing the resist layer;
developing the exposed resist layer to form an opening in the resist layer;
forming a metal wiring in the opening; and
removing the resist layer after the metal wiring is formed,
wherein, in the exposing of the resist layer, a wiring exposure pattern that corresponds to the metal wiring, and a dummy exposure pattern that does not correspond to the metal wiring are exposed to the resist layer, and
at least a part of the dummy exposure pattern is located in a region within 200 μm from an end portion of the wiring exposure pattern.

2. The method for manufacturing a wiring substrate according to claim 1,
wherein a part of the resist layer exposed by the dummy exposure pattern is fragmented and removed in the removing of the resist layer.

3. The method for manufacturing a wiring substrate according to claim 1,
wherein the dummy exposure pattern includes a mesh shape in which a plurality of lines are arranged in a lattice shape.

4. The method for manufacturing a wiring substrate according to claim 1,
wherein the dummy exposure pattern includes a dot shape in which a plurality of dots are arranged.

5. The method for manufacturing a wiring substrate according to claim 1,
wherein the dummy exposure pattern includes a linear part or a dot, and
a width of the linear part or the dot is equal to or smaller than resolution of a resist that forms the resist layer.

6. The method for manufacturing a wiring substrate according to claim 5,
wherein, in the forming of the resist layer, the resist layer is formed on a metal layer provided on the support body,
in the forming of the opening, the metal layer is exposed from the opening,
in the forming of the metal wiring, an electrolytic plating is deposited on the metal layer exposed in the opening to form the metal wiring, and
in a part of the resist layer exposed by the dummy exposure pattern, an opening from which the metal layer is exposed when being developed is not formed.

7. The method for manufacturing a wiring substrate according to claim 1,
wherein the dummy exposure pattern is a pattern capable of exposing the resist layer so that a length of a long side of a fragmented striped resist piece becomes 100 μm or less.

8. The method for manufacturing a wiring substrate according to claim 1,
wherein the dummy exposure pattern surrounds at least a part or the entirety of the wiring exposure pattern.

9. The method for manufacturing a wiring substrate according to claim 1,
wherein the resist layer is formed from a negative resist, and
a swelling rate of the resist is 30% by weight or less after immersion in a striping solution diluted 10 times at 22° C. for one minute.

10. The method for manufacturing a wiring substrate according to claim 1,
wherein, in the exposing of the resist layer, the resist layer is exposed by using a reticle including the wiring exposure pattern and the dummy exposure pattern.

11. The method for manufacturing a wiring substrate according to claim 1,
wherein, in the exposing of the resist layer, drawing is performed on the basis of an exposure drawing data including the wiring exposure pattern and the dummy exposure pattern to expose the resist layer.

12. A wiring substrate, comprising:
a support body;
a plurality of metal wirings placed on the support body; and
at least one dummy metal structure that surrounds at least a part of the plurality of metal wirings,
wherein a width of the metal wiring in a short direction is 20 μm or less,
at least a part of the dummy metal structure is located in a region within 200 μm from a wiring electrode closest to the dummy metal structure among the plurality of metal wirings, and
the dummy metal structure includes at least one among a mesh-shaped dummy metal structure in which a plurality of lines are arranged in a lattice shape, an inner dummy metal structure located between the plurality of metal wirings, and a dummy metal structure in which a plurality of dot-shaped electrodes are arranged to surround at least a part of the plurality of metal wirings.

13. A reticle for exposing a resist, comprising:
a wiring exposure pattern; and
a dummy exposure pattern in which at least a part is located within 200 μm from an end portion of the wiring exposure pattern,
wherein the dummy exposure pattern includes at least one among a mesh shape in which a plurality of lines are arranged in a lattice shape, and a dot shape in which a plurality of dots are arranged.

14. The reticle according to claim 13,
wherein the dummy exposure pattern is formed to surround at least a part or the entirety of the wiring exposure pattern.

15. A non-transitory computer-readable storage medium storing an exposure drawing data structure for an exposure apparatus for exposing a resist layer, the exposure drawing data structure comprising:
wiring exposure data configured to draw a wiring exposure pattern by the exposure apparatus; and
dummy exposure data configured to draw a dummy exposure pattern by the exposure apparatus, at least a part of the dummy exposure pattern being located within 200 μm from an end portion of the wiring exposure pattern,
wherein the dummy exposure pattern includes at least one of a mesh shape in which a plurality of lines are arranged in a lattice shape, and a dot shape in which a plurality of dots are arranged.
